(19) United States
(12) Patent Application Publication
(10) Pub. No.: US 2026/0090111 A1
(43) Pub. Date: Mar. 26, 2026

(54) Electronic Device

(71) Applicant: InnoLux Corporation, Miao-Li County (TW)

(72) Inventors: Shu-Fen LI, Miao-Li County (TW); Chuan-Chi CHIEN, Miao-Li County (TW); Chih-Lung LIN, Miao-Li County (TW); Hsiao-Feng LIAO, Miao-Li County (TW); Yung-Hsun WU, Miao-Li County (TW)

(73) Assignee: InnoLux Corporation, Miao-Li County (TW)

(21) Appl. No.: 19/286,233

(22) Filed: Jul. 30, 2025

(30) Foreign Application Priority Data
Sep. 23, 2024 (CN) 202411322347.8

(51) Int. Cl. H10D 89/60; H10D 86/40; H10D 86/60; H10H 29/85

(52) U.S. Cl. CPC H10D 89/611; H10D 86/443; H10D 86/60; H10H 29/857

(57) ABSTRACT

An electronic device includes a substrate, a first metal layer, a first insulating layer, a second metal layer, a third metal layer, an electronic component, a chip on film pad, and a flexible printed circuit pad. The substrate includes a first side and a second side. The first metal layer is disposed on the substrate. The first insulating layer is disposed on the first metal layer. The second metal layer is disposed on the first insulating layer. The third metal layer is disposed on the second metal layer. At least one portion of the third metal layer is configured to form at least one portion of an electrostatic discharge protection circuit. The electronic component includes a first terminal electrically connected to at least another portion of the third metal layer.

### BACKGROUND OF THE DISCLOSURE

### 1. Field of the Disclosure

The present invention illustrates an electronic device, and more particularly, an electronic device having an electrostatic discharge protection circuit.

### 2. Description of the Prior Art

In the realm of Micro-LED (light emitting diode) display technology, known for its high precision, brightness, and compact size, electrostatic discharge (ESD) poses a significant manufacturing hurdle. Numerous Micro-LED process layers are susceptible to ESD events during production, leading to disruptions in measurement currents, and ultimately impacting yield and reliability. ESD, characterized by the abrupt discharge of static charges through insulators or air within an extremely brief timeframe, can inflict damage, short circuits, or even open circuits on electronic components during manufacturing. The impact of ESD is particularly pronounced on miniature LED chips, potentially causing performance degradation or outright breakage.

Addressing ESD is crucial in Micro-LED manufacturing. Implementing robust static control measures, protective circuits, and process optimization, coupled with inspection and repair strategies, can effectively mitigate the detrimental effects of ESD on Micro-LED products, thus enhancing yield and reliability.

However, current ESD protection circuits fall short in structural and circuit design optimization, hindering their ability to fully control the ESD.

Consequently, the development of ESD protection circuits with optimized structures and circuitry emerges as a critical design objective.

### SUMMARY OF THE DISCLOSURE

In an embodiment of the present invention, an electronic device is disclosed. The electronic device comprises a substrate, a first metal layer, a first insulating layer, a second metal layer, a third metal layer, an electronic component, a chip on film pad, and a flexible printed circuit pad. The substrate comprises a first side and a second side corresponding to the first side. The first metal layer is disposed on the substrate. The first insulating layer is disposed on the first metal layer. The second metal layer is disposed on the first insulating layer. The third metal layer is disposed on the second metal layer. At least one portion of the third metal layer is configured to form at least one portion of an electrostatic discharge protection circuit. The electronic component comprises a first terminal electrically connected to at least another portion of the third metal layer. The chip on film pad is disposed on the first side of the substrate and electrically connected to the first metal layer and the second metal layer. The flexible printed circuit pad is disposed on the second side of the substrate and electrically connected to at least another portion of the third metal layer.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic diagram of a metal ring structure of an electronic device according to an embodiment of the present disclosure.

FIG. 2 is a schematic diagram of a first structure of the electronic device according to an embodiment of the present disclosure.

FIG. 3 is a schematic diagram of a second structure of the electronic device according to an embodiment of the present disclosure.

FIG. 4 is a schematic diagram of a third structure of the electronic device according to an embodiment of the present disclosure.

FIG. 5 is a circuit structure of a pixel unit of the electronic device in FIG. 2 to FIG. 4.

FIG. 6 is a schematic diagram of a structure of a diode circuit of the electronic device in FIG. 1 to FIG. 5.

FIG. 7 is a circuit structure of the diode circuit of the electronic device in FIG. 1 to FIG. 6.

### DETAILED DESCRIPTION

The present disclosure can be understood more fully by referencing to the following detailed description and the accompanying drawings. It should be noted that, in order to facilitate understanding and maintain the clarity of the drawings, several figures in this disclosure illustrate only a portion of the electronic device, and the specific components in the figures are not drawn to scale. Additionally, the number and size of the components in the figures are merely illustrative and are not intended to limit the scope of this disclosure.

Throughout this specification and the appended claims, certain terms are used for referring to particular components. It will be understood by those skilled in the art that manufacturers of electronic devices may use different names to refer to the same component. This document does not intend to distinguish between components that have the same function but different names.

In the following specification and claims, the terms “comprising”, “containing”, and “having” are open-ended terms and should be construed to mean “including, but not limited to”. Accordingly, whenever the description of this disclosure uses the terms “comprising”, “containing”, and/or “having”, it specifies the presence of stated features, regions, steps, operations, and/or elements, but does not preclude the presence or addition of one or more other features, regions, steps, operations, and/or elements.

Directional terms such as “upper”, “lower”, “front”, “back”, “left”, and “right” as used herein are merely in reference to the orientation as shown in the drawings. Therefore, the use of these directional terms is illustrative and not restrictive of this disclosure. In the drawings, each drawing illustrates the general features of the methods, structures, and/or materials used in a particular embodiment. However, these drawings should not be construed as defining or limiting the scope or nature encompassed by these embodiments. For example, the relative sizes, thicknesses, and positions of the various layers, regions, and/or structures may be reduced or enlarged for clarity.

When a component (such as a layer or region) is referred to as being “on” another component, it can be directly on the other component or there can be intervening components between the two. In contrast, when a component is referred to as being “directly on” another component, there are no intervening components between the two. Furthermore, when a component is referred to as being “over” another component, the two components have an upper and lower relationship in a vertical direction, and the component can be above or below the other component, depending on the orientation of the device.

It should be understood that when a component or layer is referred to as being “connected” or “coupled” to another component or layer, it can be directly connected or coupled to the other component or layer or there can be intervening components or layers between the two. In contrast, when a component is referred to as being “directly connected” or “directly coupled” to another component or layer, there are no intervening components or layers between the two. Furthermore, when a component is referred to as being “coupled to another component (or variations thereof)”, it can be directly connected to the other component or indirectly connected (i.e., electrically connected) to the other component through one or more intervening components.

The term “approximately” or “substantially” is generally interpreted to be within plus or minus 20% of a given value or range, or within plus or minus 10%, 5%, 3%, 2%, 1%, or 0.5% of a given value or range.

Ordinal terms such as “first”, “second”, etc., as used in the specification and claims to modify an element do not inherently imply or represent any previous ordinal number for that element or those elements, nor do they represent any order between one element and another or any order in a manufacturing method. The use of such ordinal terms is merely to allow for a clear distinction between elements having the same name. The same terms may not be used in the claims and the specification. Accordingly, a first element in the specification may be a second element in the claims.

It should be noted that the embodiments described below can be implemented by replacing, rearranging, or combining the features of several different embodiments to complete other embodiments without departing from the spirit of the present disclosure. As long as the features between the embodiments do not violate the spirit of the invention or conflict with each other, they can be mixed and matched at will.

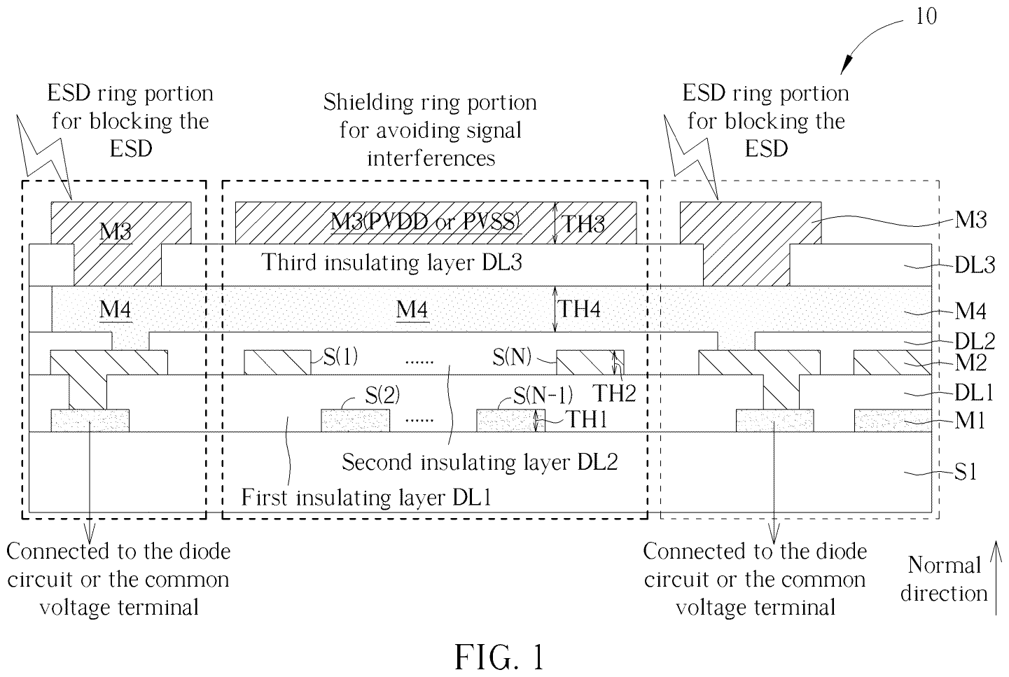

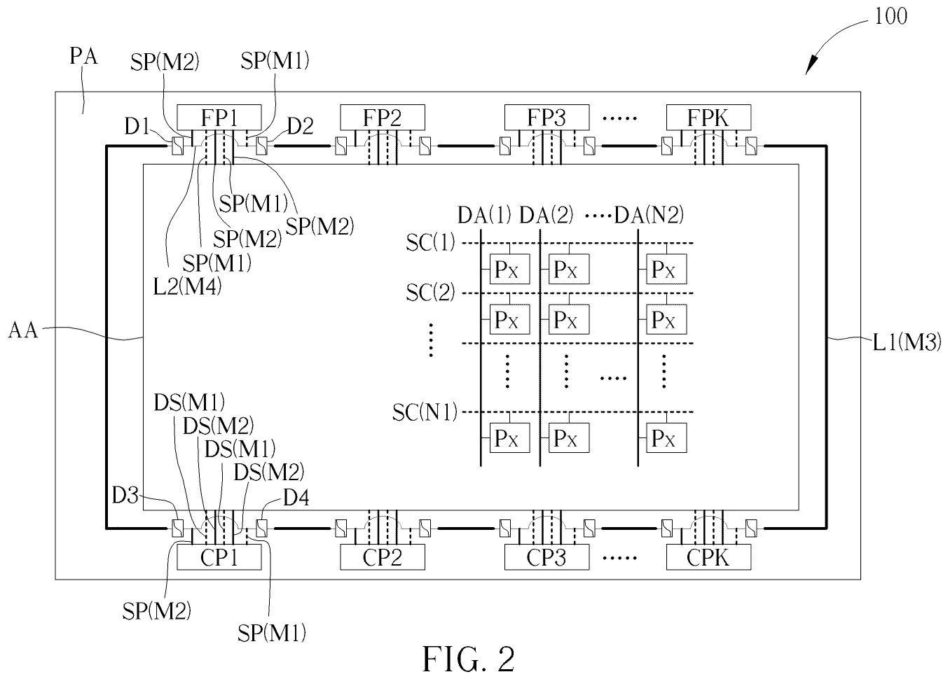

FIG. 1 is a schematic diagram of a metal ring structure 10 of an electronic device 100 according to an embodiment of the present disclosure. The electronic device 100 of the present disclosure may be a display device (such as a liquid crystal display panel), but is not limited thereto. In this disclosure, the electronic device 100 may include a display device or a backlight device, but is not limited thereto. The electronic device may be a flexible or bendable electronic device. The display device may be a non-emissive display device or a self-emissive display device. The electronic components mentioned in the electronic device may include passive components and active components, such as capacitors, resistors, inductors, diodes, transistors, etc. The diodes may include light-emitting diodes or photodiodes. The light-emitting diodes may include, for example, organic light-emitting diodes (OLEDs), mini LEDs, micro LEDs, or quantum dot LEDs, but are not limited thereto. It should be noted that the electronic device may be any combination of the aforementioned components, but is not limited thereto. The following paragraphs will use a display device as an electronic device for illustrating the content of this disclosure, but this disclosure is not limited thereto. In an embodiment, the structure of the electronic device 100 may refer to FIG. 2 to FIG. 4. The electronic device 100 has an electrostatic discharge (ESD) protection circuit. Therefore, it can effectively reduce the impact of ESD on the electronic device, thereby improving product yield and reliability. For ease of understanding, the metal ring structure of the ESD protection circuit in the electronic device 100 is shown in FIG. 1. Furthermore, the electronic device 100 can use various metal ring structures to achieve a variety of ESD protection circuit applications, as shown in FIG. 2 to FIG. 4.

Referring to FIG. 1 to FIG. 4, the electronic device 100 may be a display device, which may include a substrate S1, a first metal layer M1, a first insulating layer DL1, a second metal layer M2, a third metal layer M3, an electronic component Px_a, chip on film (COF) pads (i.e., such as COF pads CP1, CP2, CP3 . . . shown in FIG. 2 to FIG. 4), and flexible printed circuit (FPC) pads (i.e., such as FPC pads FP1, FP2, FP3 . . . shown in FIG. 2 to FIG. 4). In FIG. 1, a material of the substrate S1 can be a glass, a plastic, or any non-conductive material. The substrate S1 may include a first side and a second side corresponding to the first side. The first side and the second side may be parallel to each other. The first side and the second side may be, for example, two sides on the same surface. In some embodiments, when the substrate S1 is rectangular, the first side and the second side may also be two long sides of the rectangle. The first metal layer M1 is disposed on the substrate S1. The first insulating layer DL1 is disposed on the first metal layer M1. The second metal layer M2 is disposed on the first insulating layer DL1. The third metal layer M3 is disposed on the second metal layer M2. At least one portion of the third metal layer M3 is used for forming at least one portion of the ESD protection circuit. For example, in FIG. 1, the metal ring structure 10 of the electronic device 100 may include an ESD ring portion (or say, “a first region of the metal ring structure”) for blocking the ESD, and a shielding ring portion (or say, “a second region of the metal ring structure”) for avoiding signal interferences. Furthermore, in the ESD ring portion (the first region of the metal ring structure), at least one portion of the third metal layer M3 may be electrically connected to the second metal layer M2 and the first metal layer M1. As shown in FIG. 1, a fourth metal layer M4 may also be introduced. At least one portion of the fourth metal layer M4 may be electrically connected to the second metal layer M2. Furthermore, a second insulating layer DL2 may be disposed between at least another portion of the fourth metal layer M4 and the second metal layer M2. Similarly, at least one portion of the third metal layer M3 may be electrically connected to the fourth metal layer M4. Furthermore, a third insulating layer DL3 may be disposed between at least another portion of the third metal layer M3 and the fourth metal layer M4. In other words, the substrate S1, the first metal layer M1, the second metal layer M2, the third metal layer M3, the fourth metal layer M4, the first insulating layer DL1, the second insulating layer DL2, and the third insulating layer DL3 may form a portion of the ESD protection metal ring structure. When the electronic device 100 encounters a high-energy ESD signal, the ESD can be transmitted from the third metal layer M3 to a diode circuit or a common voltage terminal through the fourth metal layer M4, the second metal layer M2, and the first metal layer M1. Since the ESD can be leaked through a current leakage path, internal circuits of the electronic device 100 can be protected.

As mentioned previously, the metal ring structure 10 of the electronic device 100 may include the ESD ring portion (the first region of the metal ring structure) for blocking the ESD, and the shielding ring portion (the second region of the metal ring structure) for avoiding the signal interferences. In the shielding ring portion (the second region of the metal ring structure), as shown in FIG. 1, a fourth metal layer M4 may also be introduced. The second insulating layer DL2 may be disposed between the fourth metal layer M4 and the second metal layer M2. The fourth metal layer M4 is electrically insulated from the first metal layer M1 or the second metal layer M2.

Furthermore, the third insulating layer DL3 may be disposed between the third metal layer M3 and the fourth metal layer M4. The third metal layer M3 is electrically insulated from the fourth metal layer M4. Here, the third metal layer M3 may be used for providing at least one of a power signal, a high voltage signal PVDD, and a low voltage signal PVSS. In some embodiments, the third metal layer M3 in the second region of the metal ring structure may be used for providing at least one of the high voltage signal PVDD and the low voltage signal PVSS to the electronic unit Px_a, but is not limited thereto. Since the third metal layer M3, the fourth metal layer M4, the first metal layer M1, and the second metal layer M2 are all separated by insulating layers, the signal interferences between signals of different layers can be reduced. The substrate S1, the first metal layer M1, the second metal layer M2, the third metal layer M3, the fourth metal layer M4, the first insulating layer DL1, the second insulating layer DL2, and the third insulating layer DL3 may form a portion of the shielding metal ring structure for avoiding the signal interferences.

It should be understood that the electronic device 100 may further include a gate driver circuit and a data driver circuit (not shown). The gate driver circuit may be one of a gate driver on panel (GOP), an integrated circuit, a chip, a chip on film (COF) package, and a chip on glass (COG) package, and provides scanning signals for a plurality of scan lines. In some embodiments, the gate driver circuit includes at least one thin-film transistor. The data driver circuit may be one of an integrated circuit, a chip, a chip on film (COF) package, and a chip on glass (COG) package, and provides data signals for a plurality of data lines. In some embodiments, the data driver circuit may be electrically connected to a printed circuit board (PCB). The substrate S1 of FIG. 1 may include an active area AA. It should be understood that when the electronic device is a display device, the active area AA may be, for example, an area of the display device capable of displaying contents. The size and shape of the active area AA may be affected by factors such as the screen bezel, aspect ratio, and curvature. In some embodiments, the substrate S1 may further include a peripheral area PA, which is adjacent to at least one side of the active area AA. The gate driver circuit and the data driver circuit may be disposed in the peripheral area, but are not limited thereto.

The first metal layer M1 and/or the second metal layer M2 are electrically connected to the COF pads CP1 to CPK and/or the FPC pads FP1 to FPK, and are used for transmitting a plurality of signals. The signals may be defined as, but not limited to, scan signals, data signals, emission signals, power signals, high voltage signals, low voltage signals, or common voltage terminal signals (i.e., high voltage terminal VGH signals, low voltage terminal VGL signals). For example, the first metal layer M1 and/or the second metal layer M2 disposed on the first side of the substrate S1 are electrically connected to traces of the COF pads CP1 to CPK for transmitting a plurality of scan signals, a plurality of data signals, or any signal combinations to the active area AA. The first metal layer M1, the second metal layer M2, and/or the third metal layer M3 disposed on the second side of the substrate S1 are electrically connected to traces of the FPC pads FP1 to FPK for transmitting a plurality of power signals, a plurality of high voltage signals, a plurality of low voltage signals, or any signal combinations to the active area AA. In some embodiments, the first metal layer M1, the second metal layer M2, and/or the third metal layer M3 are electrically connected to the traces of the COF pads CP1 to CPK and/or the traces of the FPC pads FP1 to FPK for transmitting a plurality of common voltage terminal signals to the peripheral area PA. In some embodiments, the first metal layer M1 and/or the second metal layer M2 are electrically connected to the traces of the COF pads CP1 to CPK and/or the traces of the FPC pads FP1 to FPK for transmitting a plurality of emission signals to the active area AA.

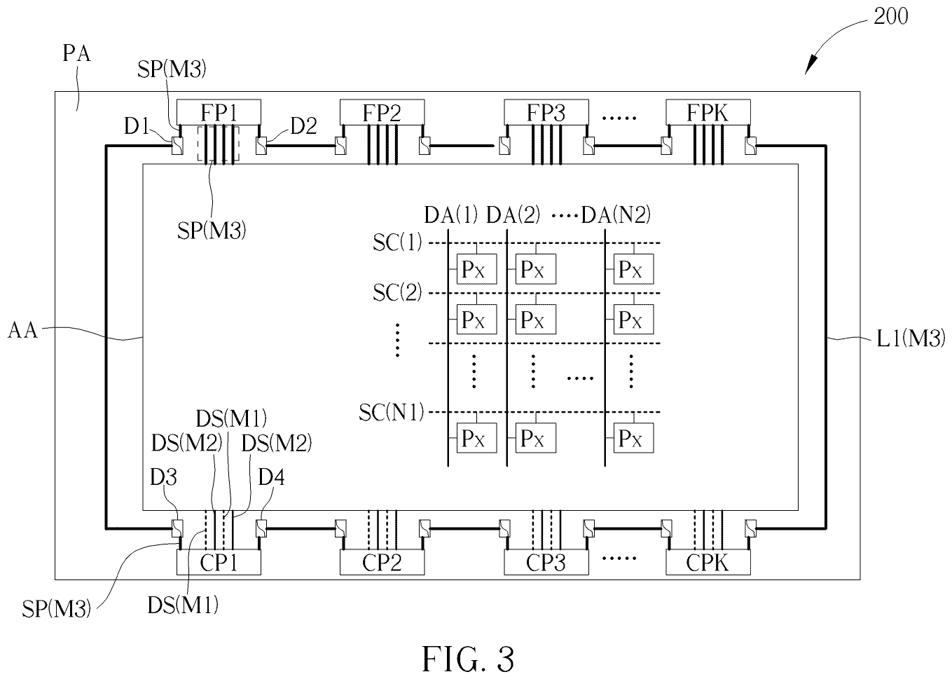

It should be understood that each of the first metal layer M1, the second metal layer M2, the third metal layer M3, and the fourth metal layer M4 may include a plurality of patterned metal portions, and the plurality of patterned metal portions of each layer may be used for transmitting the same or different signals. For example, the first metal layer M1 and/or the second metal layer M2 on the first side of the substrate S1 can be regarded as a part of the traces connecting with the COF pads, used for transmitting data signals to the data lines in the active area AA and/or transmitting scan signals to the scan lines in the active area AA. Alternatively, the first metal layer M1 and the second metal layer M2 on the second side of the substrate S1 can be regarded as a part of the traces connecting with the FPC pads, used for transmitting high voltage signals PVDD and low voltage signals PVSS. Then, the high voltage signals PVDD and low voltage signals PVSS are forwarded to the third metal layer M3 for the use of the pixel units in the active area (as shown in FIG. 2). In another embodiment, the FPC pads may provide high voltage signals PVDD and low voltage signals PVSS through the third metal layer M3 for the use of the pixel units in the active area (as shown in FIG. 3). In some embodiments, the first metal layer M1, the second metal layer M2, and/or the third metal layer M3 are electrically connected to the traces of the COF pads CP1 to CPK and/or the traces of the FPC pads FP1 to FPK for transmitting the plurality of common voltage terminal signals (i.e., high voltage terminal VGH signals, low voltage terminal VGL signals) to the ESD protection circuit.

In this disclosure, depending on different designs and requirements, the portion of the traces electrically connected to the FPC pads for transmitting the high voltage signal PVDD and the low voltage signal PVSS to the active area AA for the use of the pixel units may be any configuration or any electrical connection architecture of the first metal layer M1, the second metal layer M2, the third metal layer M3, and/or the fourth metal layer M4. The traces electrically connected to the COF pads and the FPC pads for transmitting the common voltage terminal signals to the ESD protection circuit may be any configuration or any electrical connection architecture of the first metal layer M1, the second metal layer M2, the third metal layer M3, and/or the fourth metal layer M4.

In some embodiments, as shown in FIG. 1, N signals S (1) to S(N) can be transmitted in an interlaced manner by using traces of the first metal layer M1 and the second metal layer M2. For example, in FIG. 1, the N signals may be N data signals, and the traces of the first metal layer M1 may be used for transmitting even-indexed data signals. The traces of the second metal layer M2 may be used for transmitting the odd-indexed data signals. However, the present disclosure is not limited thereto. In other embodiments, the signals S(1) to S(N) may include, for example, different signals. For example, the traces of one of the first metal layer M1 and the second metal layer M2 disposed on the first side of the substrate S1 may be used for transmitting a plurality of data signals. The traces of the other layer may be used for transmitting a plurality of scan signals. Any reasonable technical modification or hardware replacement falls into the scope of the present disclosure.

In the electronic device 100, the plurality of scan lines of the active area AA (such as the scan lines SC(1) to SC(N1) in FIG. 2 and FIG. 3) are formed by one of the first metal layer M1 and the second metal layer M2. The plurality of data lines (such as the data lines DA(1) to DA(N2) in FIGS. 2 and 3) are formed by the other of the first metal layer M1 and the second metal layer M2. N1 and N2 may be positive integers. For example, the plurality of scan lines are formed by the first metal layer M1. The plurality of data lines are formed by the second metal layer M2. The plurality of scan lines and the plurality of data lines may be disposed in an interlaced manner in the active area AA on the substrate S1 for allocating a plurality of units in the form of an array. When the electronic device 100 is a display device, the plurality of units may be, for example, a plurality of pixel units Px. Furthermore, one of the first metal layer M1 and the second metal layer M2 in the active area AA may be used for providing scan signals to the pixel units Px. The other of the first metal layer M1 and the second metal layer M2 in the active area AA may be used for providing data signals to the pixel units Px. The third metal layer M3 and/or the fourth metal layer M4 in the active area AA may be used for providing at least one of a power signal, a high voltage signal, and a low voltage signal to the pixel units Px. Details of the circuit structure of the pixel unit Px are described later.

Please continue to refer to FIG. 2 to FIG. 5, the pixel unit Px includes an electronic component Px_a. The electronic component Px_a of the electronic device 100 includes a first terminal electrically connected to at least another portion of the third metal layer M3. For example, in FIG. 2 to FIG. 5, the electronic component Px_a may be a light-emitting diode (LED). The first terminal of the electronic component Px_a may receive the low voltage signal PVSS carried by the third metal layer M3. The COF pads may be disposed on the first side of the substrate S1 and are electrically connected to the first metal layer M1 and the second metal layer M2 to provide at least one of a scan signal and a data signal to the pixel unit Px. The FPC pads may be disposed on the second side of the substrate S1 and are electrically connected to at least another portion of the third metal layer M3 to provide a high voltage signal PVDD and a low voltage signal PVSS to the pixel unit Px. For example, as shown in FIG. 3, the FPC pads may use the third metal layer M3 as traces for transmitting the high voltage signal PVDD and the low voltage signal PVSS, or as shown in FIG. 2, use the first metal layer M1 and the second metal layer M2 as traces for transmitting the high voltage signal PVDD and the low voltage signal PVSS, and then forward them to the third metal layer M3. It should be understood that the first metal layer M1 has a first thickness TH1. The second metal layer M2 has a second thickness TH2. The third metal layer M3 has a third thickness TH3. The third thickness TH3 is greater than at least one of the first thickness TH1 and the second thickness TH2. In FIG. 1, the thickness may be a maximum thickness measured along the normal direction of the substrate S1. Furthermore, the material of at least one of the second metal layer M2 and the first metal layer M1 is different from the material of the third metal layer M3. In some embodiments, the fourth metal layer M4 has a fourth thickness TH4. The fourth thickness TH4 is greater than at least one of the first thickness TH1 and the second thickness TH2. Furthermore, the material of at least one of the second metal layer M2 and the first metal layer M1 is different from the material of the third metal layer M3. For example, the resistance R of any metal layer can be expressed as follows:

$$R = ρ ( L / A )$$

Here, ρ is the resistivity. A is the cross-sectional area. L is the length. (1/ρ) is the conductivity. The cross-sectional area is positively correlated with the thickness. The third metal layer M3 and the fourth metal layer M4 can be selected to include materials with lower resistance R or higher conductivity (1/ρ) to increase the efficiency of discharging ESD. Furthermore, the first metal layer M1 and the second metal layer M2 can be selected to include materials with higher resistance R or lower conductivity (1/ρ). In one embodiment, the material of the first metal layer M1 and the second metal layer M2 may include Aluminum. The material of the third metal layer M3 and the fourth metal layer M4 may include Copper. However, the present disclosure is not limited to the materials described in the aforementioned embodiments. In other embodiments, the first metal layer M1 to the fourth metal layer M4 may include any suitable metal.

As mentioned previously, it should be understood that the third metal layer M3 and/or the fourth metal layer M4 may be used for transmitting a high voltage signal PVDD, a low voltage signal PVSS, a power signal, or a common voltage signal. Since the third metal layer M3 and/or the fourth metal layer M4 can be selected to include materials with lower resistance R or higher conductivity (1/ρ), the voltage loss (IR Drop) caused by a conductive distance can be reduced when carrying higher power voltage signals or power signals to the pixel units Px. Therefore, the performance, quality, and stability of the electronic device can be improved. Furthermore, as shown in the ESD ring portion of FIG. 1, the third metal layer M3 and the fourth metal layer M4 can be selected to include materials with lower resistance R or higher conductivity (1/ρ), and are disposed on the surface layer of the ESD ring portion. The ESD ring portion is also disposed on the surface layer of the electronic device. Therefore, the ESD ring portion can effectively discharge the ESD from the surface layer

FIG. 2 is a schematic diagram of a first structure of the electronic device 100 according to an embodiment of the present disclosure. As mentioned previously, the electronic device 100 may be a display device. For brevity, the electronic device 100 of FIG. 2 is referred to as a display device 100 hereafter. The substrate S1 of the display device 100 includes an active area AA and a peripheral area PA. In FIG. 2, the ESD protection circuit of the display device 100 may be disposed in the peripheral area PA. Details are described below. At least one portion of the ESD protection circuit may include at least one first electrostatic discharge trace L1. The ESD protection circuit may be disposed, for example, in the peripheral area PA. The first electrostatic discharge trace L1 may be formed by at least one portion of the third metal layer M3. Therefore, its nomenclature is written as L1(M3). The ESD protection circuit of the electronic device 100 may further include at least one second electrostatic discharge trace L2. Furthermore, the at least one second electrostatic discharge trace L2 may be formed by at least one portion of the fourth metal layer M4. Therefore, its nomenclature is written as L2(M4). The ESD protection circuit may further include a plurality of diode circuits. The at least one first electrostatic discharge trace L1(M3), the at least one second electrostatic discharge trace L2(M4), and the diode circuits are connected to form an ESD protection ring. For example, in FIG. 2, the ESD protection structure corresponding to the FPC pad FP1 includes a first electrostatic discharge trace L1 (formed by the third metal layer M3), a diode circuit D1, a second electrostatic discharge trace L2 (formed by the fourth metal layer M4), and a diode circuit D2, which is beneficial for effectively discharging the ESD from the FPC pad FP1. The ESD protection structures corresponding to the FPC pad FP2, the FPC pad FP3, etc., are similar and will not be described in detail. The ESD protection structure corresponding to the COF pad CP1 includes a first electrostatic discharge trace L1 (formed by the third metal layer M3), a diode circuit D3, a second electrostatic discharge trace L2 (formed by the fourth metal layer M4), and a diode circuit D4, which is beneficial for effectively discharging the ESD from the COF pad CP1. The ESD protection structures corresponding to the COF pad CP2, the COF pad CP3, etc., are similar and will not be described in detail. Therefore, the aforementioned ESD protection structures can form a part of a metal ring (or a part of the ESD protection ring). As a result, the ESD protection circuit of the electronic device 100 can be implemented by the structure of the annular metal ring. Furthermore, as mentioned previously, the first metal layer M1 and the second metal layer M2 may be used for transmitting a plurality of signals. For ease of understanding, in FIG. 2, the voltage signal SP includes at least one of a high voltage signal, a power signal, a low voltage signal, and a common voltage terminal signal. Here, SP(M1) indicates the voltage signal SP carried by the first metal layer M1. SP(M2) indicates the voltage signal SP carried by the second metal layer M2. The data signal DS includes at least one of a scan signal and a data signal. DS(M1) indicates the data signal DS carried by the first metal layer M1. DS(M2) indicates the data signal DS carried by the second metal layer M2. For the FPC pads (such as FPC pad FP1, FPC pad FP2, FPC pad FP3 . . . ), the high voltage signal and/or the low voltage signal can be transmitted to the active area AA through the first metal layer M1 and/or the second metal layer M2. Then, the high voltage signal PVDD and/or the low voltage signal PVSS can be transmitted to the pixel units Px in the active area AA through the third metal layer M3 and/or the fourth metal layer M4. In addition, the FPC pads can transmit the common voltage terminal signal to the ESD protection circuit in the peripheral area PA through the first metal layer M1 and/or the second metal layer M2. In some embodiments, the FPC pads transmit the high voltage signal PVDD and/or the low voltage signal PVSS to the pixel units Px in the active area AA through the third metal layer M3 and/or the fourth metal layer M4. For the COF pads (such as COF pad CP1, COF pad CP2, COF pad CP3 . . . ), the scan signal and/or the data signal can be transmitted to the pixel units Px in the active area AA through the first metal layer M1 and/or the second metal layer M2. In addition, the COF pads can transmit the common voltage terminal signal to the ESD protection circuit in the peripheral area PA through the first metal layer M1 and/or the second metal layer M2. In some embodiments, the emission signal can be transmitted to the pixel units Px in the active area AA through the traces of the COF pads CP1 to CPK and/or the traces of the FPC pads FP1 to FPK.

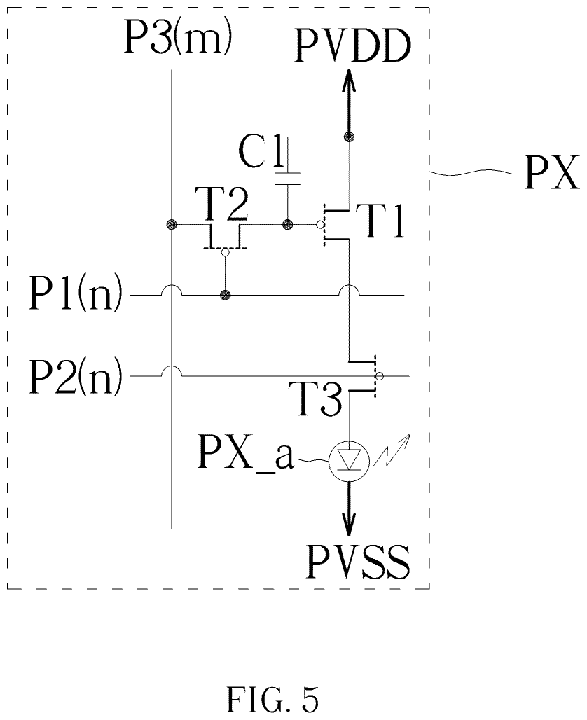

FIG. 3 is a schematic diagram of a second structure of the electronic device 100 according to an embodiment of the present disclosure. To avoid ambiguity, the electronic device in FIG. 3 is referred as an electronic device 200 hereinafter. As mentioned previously, the electronic device 200 may be a display device. For brevity, the electronic device 200 of FIG. 3 is referred as a display device 200. Similarly, the substrate S1 of the display device 200 includes an active area AA and a peripheral area PA. In FIG. 3, the ESD protection circuit of the display device 200 may be disposed in the peripheral area PA. Details are described below. In the display device 200, at least one portion of the ESD protection circuit may include at least one first electrostatic discharge trace L1. The first electrostatic discharge trace L1 may be formed by at least one portion of the third metal layer M3. Therefore, its nomenclature is written as L1(M3). The ESD protection circuit may further include a plurality of diode circuits. The at least one first electrostatic discharge trace L1(M3) and the diode circuits form a part of an ESD protection ring. According to FIG. 3, the at least one first electrostatic discharge trace L1(M3), the plurality of diode circuits, and bonding elements in the COF pads and the FPC pads are connected to form an ESD protection ring. For example, in FIG. 3, the FPC pad FP1 may be connected to the first electrostatic discharge trace L1 (formed by the third metal layer M3). The first electrostatic discharge trace L1(M3) may be used for discharging the ESD of the FPC pad FP1 through the diode circuit D1 and the diode circuit D2. The ESD protection structures corresponding to the FPC pad FP2, the FPC pad FP3, etc., are similar and will not be described in detail. The COF pad CP1 may be connected to the first electrostatic discharge trace L1(formed by the third metal layer M3). The first electrostatic discharge trace L1(M3) may be used for discharging the ESD of the COF pad CP1 through the diode circuit D3 and the diode circuit D4. The ESD protection circuit of the display device 200 can be implemented by the structure of an annular metal ring. Furthermore, as mentioned previously, the first metal layer M1 and the second metal layer M2 may be used for transmitting signals. For ease of understanding, the voltage signal SP in FIG. 3 includes at least one of a high voltage signal, a power signal, a low voltage signal, and a common voltage terminal signal. SP(M1) indicates the voltage signal SP carried by the first metal layer M1. SP(M2) indicates the voltage signal SP carried by the second metal layer M2. SP(M3) indicates the voltage signal SP carried by the third metal layer M3. The data signal DS includes at least one of scan line data and data line data. Furthermore, DS(M1) indicates the data signal DS carried by the first metal layer M1. DS(M2) indicates the data signal DS carried by the second metal layer M2. For the FPC pads (such as FPC pad FP1, FPC pad FP2, FPC pad FP3 . . . ), the high voltage signal PVDD and the low voltage signal PVSS can be carried by the third metal layer M3 for the use of the pixel units Px. In addition, the FPC pads can transmit the common voltage terminal signal to the ESD protection circuit in the peripheral area PA through the third metal layer M3. For the COF pads (such as COF pad CP1, COF pad CP2, COF pad CP3 . . . ), the scan signal and/or the data signal can be transmitted to the active area AA through the first metal layer M1 and/or the second metal layer M2. In addition, the COF pads can transmit the common voltage terminal signal to the ESD protection circuit in the peripheral area PA through the third metal layer M3. In some embodiments, the emission signal can be transmitted to the pixel units Px in the active area AA through the traces of the COF pads CP1 to CPK and/or the traces of the FPC pads FP1 to FPK. Furthermore, the circuit structure of the pixel unit Px of the display device 200 are the same as those of the display device 100. Details will be described later in FIG. 5.

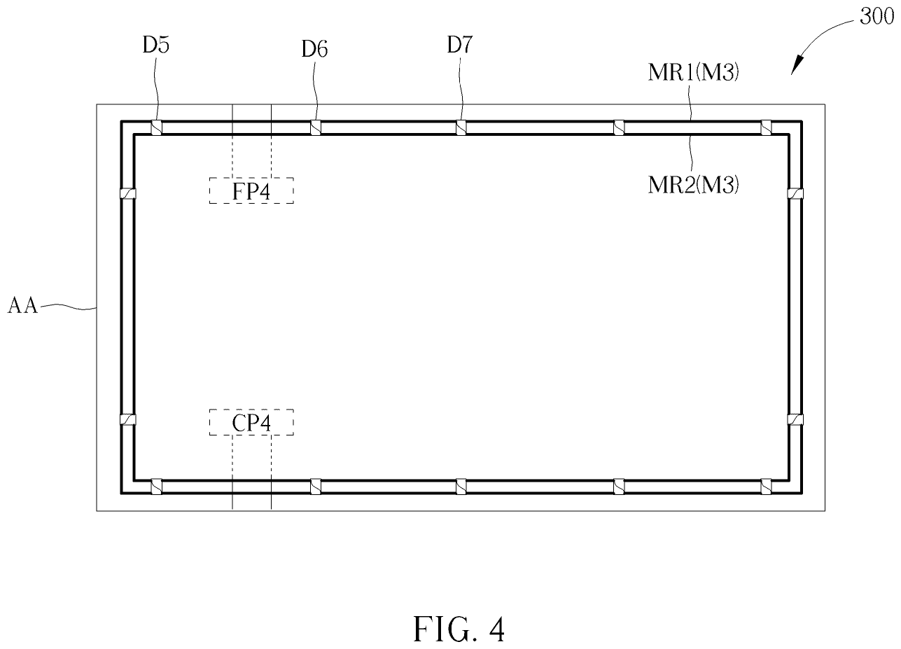

FIG. 4 is a schematic diagram of a third structure of the electronic device 100 according to an embodiment of the present disclosure. To avoid ambiguity, the electronic device in FIG. 4 is referred as an electronic device 300 hereinafter. For brevity, the electronic device 300 in FIG. 4 is referred as a display device 300. The substrate S1 of the display device 300 includes an active area AA. The ESD protection circuit of the display device 300 may be disposed within the active area AA. Details are described below. At least one portion of the ESD protection circuit may include an inner electrostatic discharge trace MR2 and an outer electrostatic discharge trace MR1. The inner electrostatic discharge trace MR2 and the outer electrostatic discharge trace MR1 are formed by at least one portion of the third metal layer M3. One of the inner electrostatic discharge trace MR2 and the outer electrostatic discharge trace MR1 may be connected to, for example, a high voltage terminal VGH and/or a low voltage terminal VGL. Furthermore, the ESD protection circuit may include a plurality of diode circuits (such as the diode circuits D5, D6, D7 . . . ). The inner electrostatic discharge trace MR2 and the outer electrostatic discharge trace MR1 may be connected through the diode circuits. Therefore, the inner electrostatic discharge trace MR2, the diode circuits (such as the diode circuits D5, D6, D7 . . . ), and the outer Electrostatic discharge trace MR1 may form a metal ring (i.e., an ESD protection ring). The ESD protection circuit of the display device 300 can be implemented by the ESD protection ring. It should be understood that, in the display device 300, the FPC pad FP4 may be connected to the active area AA on a front side through the metal layers disposed on a back side of the substrate S1. Similarly, the COF pad CP4 may also be connected to the active area AA on the front side through the metal layers disposed on the back side of the substrate S1. The FPC pad FP4 transmits at least one of a power signal, a common voltage terminal signal, a high voltage signal PVDD, and a low voltage signal PVSS to the active area AA. The common voltage terminal signal is transmitted to the ESD protection ring. The high voltage signal PVDD and the low voltage signal PVSS are transmitted to the pixel unit Px. The COF pad CP4 transmits at least one of a scan signal and a data signal to the pixel unit Px. In some embodiments, the COF pad CP4 transmits the common voltage terminal signal to the ESD protection ring. In some embodiments, the COF pad CP4 and/or the FPC pad FP4 transmit an emission signal to the pixel units Px in the active area AA. The circuit structure of the pixel unit Px of the display device 300 are the same as those of the display device 100 and the display device 200. Details will be described in FIG. 5.

FIG. 5 is the circuit structure of the pixel unit Px of the electronic devices 100 to 300. The electronic devices 100 to 300 are also referred as display devices 100 to 300. The active area AA of the display device may include a plurality of pixel units Px. Each pixel unit Px includes a plurality of transistors. The pixel unit Px includes the electronic component Px_a. The electronic component Px_a includes a first terminal electrically connected to at least another portion of the third metal layer M3 for receiving the low voltage signal PVSS carried by the third metal layer M3. The electronic component Px_a further includes a second terminal. One of the transistors is electrically connected to the second terminal of the electronic component Px_a. The electronic component Px_a may be a light-emitting diode (LED). In FIG. 5, the pixel unit Px may include a first transistor T1, a second transistor T2, a third transistor T3, a capacitor C1, and the electronic component Px_a. The first transistor T1 includes a first terminal used for receiving the high voltage signal PVDD, a control terminal, and a second terminal. The capacitor C1 includes a first terminal coupled to the first terminal of the first transistor T1 and a second terminal coupled to the control terminal of the first transistor T1. The second transistor T2 includes a first terminal coupled to the control terminal of the first transistor T1, a control terminal coupled to an n-th scan line P1(n), and a second terminal coupled to an m-th data line P3(m). The third transistor T3 includes a first terminal coupled to the second terminal of the first transistor T1, a control terminal coupled to an n-th emission line P2(n), and a second terminal coupled to the second terminal of the electronic component Px_a. Furthermore, the first terminal of each transistor may be a drain terminal. The control terminal may be a gate terminal. The second terminal may be a source terminal. Furthermore, the gate terminal may be formed by or electrically connected to one of the first metal layer M1 and the second metal layer M2. The source terminal and the drain terminal may be formed by or electrically connected to the other of the first metal layer M1 and the second metal layer M2. For example, in FIG. 5, the high voltage signal PVDD and the low voltage signal PVSS may be carried by the third metal layer M3 and/or the fourth metal layer M4. As mentioned previously, since the third metal layer M3 and/or the fourth metal layer M4 can be selected to include materials with lower resistance or higher conductivity, the voltage loss caused by the conductive distance can be reduced. Therefore, the third metal layer M3 and/or the fourth metal layer M4 can be used for improving the performance, quality, and stability of the electronic device. The source terminals and the drain terminals of the first transistor T1, the second transistor T2, and the third transistor T3 may be electrically connected to the second metal layer M2. The gate terminals of the first transistor T1, the second transistor T2, and the third transistor T3 may be electrically connected to the first metal layer M1. Here, the first transistor T1, the second transistor T2, and the third transistor T3 may be P-type metal-oxide-semiconductor field-effect transistors (PMOS). However, the present disclosure is not limited thereto. Any reasonable technology modification or hardware replacement falls into the scope of the present disclosure.

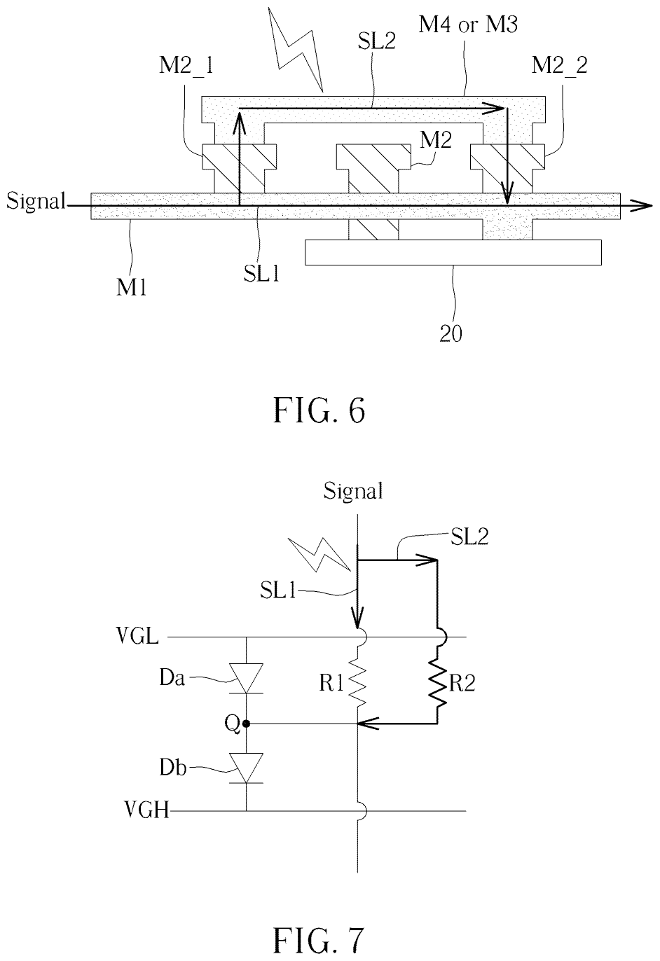

FIG. 6 is a schematic diagram of a structure of a diode circuit of the electronic devices 100 to 300 (say, display devices 100 to 300). As mentioned previously, the display devices 100 to 300 can use metal layers in conjunction with diode circuits for discharging the ESD. To enhance high voltage resistance and current leakage capacity of the ESD protection circuit, the diode circuit may introduce an additional leakage path. Details are described below. In the structure of the diode circuit in the ESD protection circuit, the fourth metal layer M4 may be introduced. The fourth metal layer M4 may be electrically connected to the first metal layer M1 through at least one portion of the second metal layer M2_1. The fourth metal layer M4 may also be electrically connected to the first metal layer M1 through at least another portion of the second metal layer M2_2. The first metal layer M1 is connected to a semiconductor material 20 of at least one diode. Therefore, in FIG. 6, when the electronic device is affected by the ESD current, the ESD current can be transmitted to the semiconductor material 20 of the at least one diode through a first current leakage path SL1 and a second current leakage path SL2. For example, the first current leakage path SL1 is used for transmitting the ESD current from the first metal layer M1 to the semiconductor material 20 of the at least one diode. The second current leakage path SL2 is used for transmitting the ESD current from the first metal layer M1 to the semiconductor material 20 of the at least one diode through the at least one portion of the second metal layer M2_1, the fourth metal layer M4, and at least another portion of the second metal layer M2_2. Therefore, since the ESD protection circuit introduces two current leakage paths, its high voltage resistance and current leakage capacity can be enhanced. As a result, when receiving extremely high ESD, its circuit structure will not immediately break or enter an open circuit state.

It should be understood that, although FIG. 6 introduces the fourth metal layer M4 as a part of the additional leakage path (the second current leakage path SL2), in other embodiments, the third metal layer M3 can also be introduced as a part of the additional leakage path (the second current leakage path SL2). This is because the third metal layer M3 or the fourth metal layer M4 can be selected to include materials with lower resistance or higher conductivity. Therefore, both the third metal layer M3 and the fourth metal layer M4 are suitable for discharging the ESD.

FIG. 7 is a circuit structure of the diode circuit of the electronic devices 100 to 300 (say, display devices 100 to 300). FIG. 7 is an equivalent circuit of FIG. 6. The diode circuit includes a first diode Da, a second diode Db, a first equivalent resistance R1, and a second equivalent resistance R2. The first equivalent resistance R1 includes a first terminal used for receiving a signal, and a second terminal. The second equivalent resistance R2 includes a first terminal coupled to the first terminal of the first equivalent resistance R1, and a second terminal coupled to the second terminal of the first equivalent resistance R1. The first diode Da includes a cathode coupled to the second terminal of the second equivalent resistance R2, and an anode coupled to the low voltage terminal VGL. The second diode Db includes a cathode coupled to the high voltage terminal VGH, and an anode coupled to the cathode of the first diode Da. In FIG. 7, the first equivalent resistance R1 of the first current leakage path SL1 is greater than or equal to the second equivalent resistance R2 of the second current leakage path SL2. This is explained as follows. When the electronic device 100 encounters a high-energy ESD event, the ESD current will be transmitted to a node Q through the first current leakage path SL1 and the second current leakage path SL2. When the first equivalent resistance R1 of the first current leakage path SL1 is greater than or equal to the second equivalent resistance R2 of the second current leakage path SL2, a discharge current passing through the first current leakage path SL1 is less than or equal to a discharge current passing through the second current leakage path L2. Therefore, it can be ensured that the components on the first current leakage path SL1 may not be damaged or burned out to enter the open circuit state. For example, in FIG. 7, when the ESD voltage is an extremely positive voltage, it will cause the second diode Db to enter a conductive state (cross voltage of the second diode Db>threshold voltage). Therefore, the ESD can be transmitted through the first current leakage path SL1 and the second current leakage path SL2 to the second diode Db and can be discharged to the high voltage terminal VGH. Therefore, the internal components of the electronic device 100 can be protected. When the ESD voltage is an extremely negative voltage, it will cause the first diode Da to enter the conductive state (cross voltage of the first diode Da>threshold voltage). Therefore, a current transmitted from the low voltage terminal VGL can be compensated to the extremely negative voltage through the first diode Da, the first current leakage path SL1, and the second current leakage path SL2. Therefore, regardless of whether it is a positive ESD voltage or a negative ESD voltage, the ESD protection circuit can effectively protect the components of the electronic devices 100 to 300. Furthermore, it should be understood that the high voltage signal PVDD and the low voltage signal PVSS in FIG. 5 are configured as two voltage signals used for driving the pixel unit Px. For example, the high voltage signal PVDD may be an operating voltage. The low voltage signal PVSS may be a ground voltage. In some embodiments, the high voltage signal PVDD may be a positive voltage. The low voltage signal PVSS may be a negative voltage, but is not limited thereto. The high voltage terminal VGH and the low voltage terminal VGL in FIG. 7 are configured as two terminals used for discharging or compensating the ESD. For example, the high voltage terminal VGH may be used for discharging the extremely positive ESD voltage. The low voltage terminal VGL may be used for compensating the extremely negative ESD voltage.

To sum up, the present disclosure describes an electronic device. The electronic device includes an ESD protection circuit. The ESD protection circuit can be implemented by an annular metal layer. The annular metal layer has a stacked structure, which can be formed by a plurality of metal layers with different resistances and insulating layers. The electronic device may be a display device. The ESD protection circuit of the present disclosure can be flexibly disposed in the active area or the peripheral area of the display device with different structures according to the design requirements of the display device. Furthermore, the ESD protection circuit can introduce a plurality of current leakage paths, which can ensure that the components on the current paths will not be damaged or burned out to enter the open circuit state. Further, the features between various embodiments can be mixed and matched at will as long as they do not violate the concept of the invention or conflict with each other. Since the electronic device of the present disclosure can optimize the structures and materials of the ESD protection circuit, the ESD can be effectively controlled.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device comprising:
a substrate comprising:
a first side; and
a second side corresponding to the first side;
a first metal layer disposed on the substrate;
a first insulating layer disposed on the first metal layer;
a second metal layer disposed on the first insulating layer;
a third metal layer disposed on the second metal layer, wherein at least one portion of the third metal layer is configured to form at least one portion of an electrostatic discharge protection circuit;
an electronic component comprising:
a first terminal electrically connected to at least another portion of the third metal layer;
a chip on film (COF) pad disposed on the first side of the substrate and electrically connected to the first metal layer and the second metal layer; and
a flexible printed circuit (FPC) pad disposed on the second side of the substrate and electrically connected to at least another portion of the third metal layer.

2. The electronic device of claim 1, wherein the first metal layer has a first thickness, the second metal layer has a second thickness, the third metal layer has a third thickness, and the third thickness is greater than at least one of the first thickness and the second thickness.

3. The electronic device of claim 1, wherein a material of one of the second metal layer and the first metal layer is different from a material of the third metal layer.

4. The electronic device of claim 1, wherein a scan line of the electronic device is formed by one of the first metal layer and the second metal layer, a data line of the electronic device is formed by another one of the first metal layer and the second metal layer, the scan line and the data line are alternately disposed on the substrate for allocating a pixel unit, and one of the first metal layer and the second metal layer is configured to provide a data signal to the pixel unit.

5. The electronic device of claim 4, wherein the electronic component further comprises a second terminal, the pixel unit comprises a plurality of transistors, and one of the plurality of transistors is electrically connected to the second terminal of the electronic component.

6. The electronic device of claim 4, wherein the pixel unit comprises a plurality of transistors, each of the transistors comprises a gate terminal, a source terminal and, a drain terminal, one of the first metal layer and the second metal layer is electrically connected to the gate terminal, and another one of the first metal layer and the second metal layer is electrically connected to the source terminal and the drain terminal.

7. The electronic device of claim 1, wherein at least one portion of the electrostatic discharge protection circuit comprises at least one first electrostatic discharge trace.

8. The electronic device of claim 7, wherein the electrostatic discharge protection circuit further comprises a plurality of diode circuits, and the at least one first electrostatic discharge trace and the diode circuits form a portion of an electrostatic discharge protection ring.

9. The electronic device of claim 7, further comprising:
a fourth metal layer disposed between the second metal layer and the third metal layer;
wherein at least one second electrostatic discharge trace of the electrostatic discharge protection circuit is formed by at least one portion of the fourth metal layer, the electrostatic discharge protection circuit further comprises a plurality of diode circuits, and the at least one first electrostatic discharge trace, the at least one second electrostatic discharge trace, and the diode circuits are connected to form an electrostatic discharge protection ring.

10. The electronic device of claim 1, wherein at least a portion of the electrostatic discharge protection circuit comprises an inner electrostatic discharge trace and an outer electrostatic discharge trace, the inner electrostatic discharge trace and the outer electrostatic discharge trace are formed by the at least a portion of the third metal layer, the electrostatic discharge protection circuit comprises a plurality of diode circuits, the inner electrostatic discharge trace, and the outer electrostatic discharge trace are connected through the diode circuits, and the inner electrostatic discharge trace, the diode circuits, and the outer electrostatic discharge trace form an electrostatic discharge protection ring.

11. The electronic device of claim 1, wherein the third metal layer is electrically connected to the first metal layer through at least one portion of the second metal layer, the third metal layer is electrically connected to the first metal layer through at least another portion of the second metal layer, and the first metal layer is connected to a semiconductor material of at least one diode.

12. The electronic device of claim 11, wherein when the electronic device is affected by an electrostatic discharge current, the electrostatic discharge current is transmitted to the at least one diode through a first current leakage path and a second current leakage path, and a first equivalent resistance of the first current leakage path is greater than or equal to a second equivalent resistance of the second current leakage path.

13. The electronic device of claim 12, wherein the first current leakage path is configured to transmit the electrostatic discharge current from the first metal layer to the at least one diode, and the second current leakage path is configured to transmit the electrostatic discharge current from the first metal layer to the at least one diode through the at least one portion of the second metal layer, the third metal layer, and the at least another portion of the second metal layer.

14. The electronic device of claim 1, wherein a metal ring structure of the electrostatic discharge protection circuit comprises a first region and a second region, the first region is configured to block electrostatic discharge, and the second region is configured to avoid generating signal interferences.

15. The electronic device of claim 14, wherein the at least one portion of the third metal layer is electrically connected to the second metal layer and the first metal layer within the first region of the metal ring structure of the electrostatic discharge protection circuit.

16. The electronic device of claim 15, further comprising:
a fourth metal layer disposed between the second metal layer and the third metal layer;
wherein the fourth metal layer is electrically connected to at least one portion of the second metal layer, and electrically connected to the at least one portion of the third metal layer.

17. The electronic device of claim 14, further comprising:
a fourth metal layer disposed between the second metal layer and the third metal layer; and
a second insulating layer disposed between the second metal layer and the fourth metal layer;
wherein the fourth metal layer and the second metal layer are electrically isolated within the second region of the metal ring structure of the electrostatic discharge protection circuit.

18. The electronic device of claim 14, further comprising:
a fourth metal layer disposed between the second metal layer and the third metal layer; and
a third insulating layer disposed between the third metal layer and the fourth metal layer;
wherein the fourth metal layer and the third metal layer are electrically isolated within the second region of the metal ring structure of the electrostatic discharge protection circuit.

19. The electronic device of claim 1, wherein the at least another portion of the third metal layer is configured to provide at least one of a high voltage signal and a low voltage signal to the electronic component.

20. The electronic device of claim 19, wherein the substrate comprises an active region, the FPC pad transmits at least one of the high voltage signal and the low voltage signal to the active region through the first metal layer and the second metal layer, and transmits at least one of the high voltage signal and the low voltage signal to the electronic component through the third metal layer.
